(19) United States
(12) Patent Application Publication
(10) Pub. No.: US 2011/0285401 A1
(43) Pub. Date: Nov. 24, 2011

(54) Method for Determining the Lifetime of Interconnects

(75) Inventor: Lucile Arnaud, Saint Martin D'Heres (FR)

(73) Assignee: Commissariat A L'Energie Atomique Et Aux Energies Alternatives, Paris (FR)

(21) Appl. No.: 12/784,733

(22) Filed: May 21, 2010

(51) Int. Cl. G01R 31/04

(52) U.S. Cl. 324/538

(57) ABSTRACT

A method for characterizing the lifetime, extrapolated to working conditions, of an interconnect structure representative of a technology in a given product uses modeling of an electromigration phenomenon by Black's equation, but applied separately to groups of test samples of the structure which are determined on the basis of the resistance increase value of the samples at the failure time. The more refined approach carried out in this way allows better characterization of the interconnect structure in relation to operational working conditions, corresponding to an application or a finished product, making it possible to check whether the expected lifetime can be guaranteed regardless of the failure mechanism at play in said structure.

### TECHNICAL FIELD

The present invention relates to the reliability of interconnects in integrated circuits, that is to say physical structures which make it possible to convey an electrical signal from one point to another in an integrated circuit. It relates more particularly to determination of the lifetime of the interconnects for a given technology node, failure rate and conditions of use.

### BACKGROUND OF THE INVENTION

The technological developments which have made it possible to increase the performance of integrated circuits, in particular increasing the integration density and their working speed, have repercussions on the characteristics, performance and reliability of the interconnects.

Each technological advance is manifested by a reduction of the dimensions of the interconnect lines (width, interline space) which is compatible with the increase in the number of interconnect lines to be produced on an increasingly integrated circuit (that is to say one on which more and more components are integrated) and in parallel by an increase in the current densities on these lines, which are compatible with the expected working speeds.

In the most recent technology nodes, the interconnects are thus made of copper by a damascene method with steps of depositing thin layers of insulator, copper, etch stop, copper diffusion barrier, and vias between the various interconnect levels in order to connect the interconnect lines to one another.

FIG. 1 is a schematic view in cross section of an example of an interconnect line produced according to a damascene method. In the example, there is a stack of three insulator levels L₁, L₂, L₃ on a substrate S. A trench is produced in the middle insulator layer, L₂, in order to deposit there the conductive metal m, typically copper, which forms the conductive line. A barrier layer b_{d} against diffusion of the metal m, typically TaN/Ta when the metal m is copper, is present at the bottom and on the walls of the trench, and stop layers bₐ, for example layers of SiCN, are provided at the interface with the upper L₃ and lower L₁ insulator layers.

The interconnect structures are sensitive to the phenomenon of electromigration. Specifically, as is known, electromigration leads to the creation or growth of cavities or “voids” in the conductive material, which can cause physical failures or cuts of the lines. This phenomenon of the interconnects failing is exacerbated by the reduction in the dimensions of the lines and the increase in the current density.

The interconnect failures cause malfunctions of the integrated circuits, and therefore have a direct impact on the lifetime of these circuits.

For these reasons, with each technology node and for a given integrated circuit, it is necessary to characterize the reliability of the interconnects, that is to say their lifetime, in relation to the electromigration phenomenon, taking into account the operational working conditions of the integrated circuit in question (max current density, working temperature) and an acceptable failure rate (it will be recalled that the failure rate is the percentage of samples which will suffer malfunction before the median lifetime determined for the product). Specifically, an integrated circuit or a finished product, for example a cell phone or an on-board remote control for automobiles, is sold on the market with a guaranteed lifetime and failure rate, for example 10 years with an accepted failure rate of 0.1%. Characterizing the lifetime of the interconnects forms a part of the characterization of the lifetime of the integrated circuit.

More generally, with each new integrated circuit design, attempts are made to determine the rules which connect the current density, temperature and failure rate. For example, this entails determining the maximum acceptable current density for a determined lifetime, failure rate and temperature of use. Alternatively, the lifetime may be determined for a determined current density, temperature and failure rate.

This determination involves electromigration test scenarios which consist in subjecting a population of samples to a high current density and high temperature, with a view to prematurely bringing about ageing, and therefore an interconnect failure, and in recording the resistance of the interconnect structure during the time of exposure to the test.

This is because the increase in resistance evinces a physical failure in the copper line due to electromigration. It is known that the current then flows through other, more resistive paths, notably the diffusion barriers. This leads to an abrupt increase in the resistance of the interconnect structure at failure, which makes it possible to detect the instant of the failure.

Thus, for each new product/technology node, a characteristic interconnect structure representative of the interconnects for the product in question is defined, and a population of corresponding samples is fabricated, all of which are identical, on which the characterization of the lifetime will be carried out.

In terms of electromigration, the lines and the vias are elements which are important and should therefore be present in the characteristic interconnect structure to be tested. A characteristic interconnect structure is thus at least a double-level structure with one line and two vias, at either end of the line, for connecting the line to two current supply electrodes. Such a structure is represented schematically in FIG. 2: on one conductor level, a copper interconnect line 1 of length L, width w and height h, and two copper-filled vias 2, 3 connecting this line at either end to conductive electrodes 4, 5 also made of copper, which are produced according to the same damascene method as the line, on a different conductor level. These conductive electrodes are used as current supply electrodes for the test. The materials, the dimensions (DRM design rules) and the steps in the method of fabricating these samples are representative of the product in question. Notably the width w and the thickness, or height, h of the lines and vias correspond to the smallest dimensions achievable for the technology node in question, according to the design rules (DRM Design Rule Model) defined for the technology. For the 45 nm technology node, for example, typically hₘᵢₙ=150 nm and wₘᵢₙ=70 nm. Samples of different widths, which are a multiple of the minimum value for the technology, for example 2 or 3 times wₘᵢₙ, may be produced in order to characterize the interconnect structures with these various widths which correspond to real lines produced on a product.

The purpose of each test scenario is to accelerate the effects of electromigration in the sample being tested. Each scenario essentially consists in applying a current I between the two supply electrodes of each tested sample, with a determined current density J, at a determined temperature T and for a determined length of time, and in measuring the resistance of each sample. The resistance of each sample is typically measured by means of a device for measuring the voltage between the two supply electrodes, as illustrated schematically in FIG. 2. The test structure may be produced according to the configuration illustrated in FIG. 2, with the interconnect line 1 produced on the lower layer and the supply electrodes on the upper layer, or in the reverse configuration with the interconnect line produced on a layer higher than the layer of the supply electrodes.

In practice, a test bench specially dedicated to electromigration is used in order to apply these scenarios to the test samples. Such a bench typically comprises ovens in which the samples are placed. During the test, the samples are continuously stressed with a temperature and current, and the value of the resistance is measured and recorded. The variation of the resistance during the stress time is thus obtained for each sample, which makes it possible to determine the failure time corresponding to a sharp increase in the resistance.

Statistical treatments carried out on the measured failure times then make it possible to ascertain the lifetime for operational conditions of the product in question and a given failure rate.

These statistical treatments are well known to the person skilled in the art. They will not be described in detail. It is simply useful to recall that the methods for characterizing the lifetime of interconnects use modeling of the phenomenon of failure by electromigration for a given current density J and temperature T, described by Black's equation which can be written:

MTTF=A_{b}Jⁿ^{_{b}}·e^{E}^{ₐ}^{/kT} (EQB),
where MTTF (Mean Time To Failure) is the median lifetime under the conditions (J,T).

This Black's equation EQB is widely used in the field of characterizing the reliability of interconnects.

This equation contains A_{b} expressed in seconds, Eₐ (for “activation energy”) expressed in joules, n_{b} (no units), J the current density (in amperes per square meter), k Boltzmann's constant (in joules per kelvin) and T the temperature (in kelvins).

For an interconnect structure characteristic of a given technology node/product, the Black parameters A_{b}, Eₐ, n_{b} and a standard deviation parameter σ of the lognormal distribution are the modeling parameters of the failure mechanism of the interconnect structure in question, for the phenomenon of failure by electromigration. They are determined on the basis of statistical processing of the failure times of the interconnects, measured on samples subjected to different test scenarios (premature ageing), of which there are at least three, each scenario being characterized by a determined current density and test temperature.

It is then possible to use Black's equation, with the extracted parameters A_{b}, Eₐ, n_{b} and σ, in order to determine the extrapolated lifetime of the interconnect structure in question, under the operational conditions of the product and for a given failure rate.

To these ends, it is in practice necessary to use at least three different test scenarios with at least two different conditions for the current density and two different conditions for the temperature. Each scenario is applied to a population of identical samples. For example, three populations of test samples are produced, all of which are identical, and a respective test scenario is applied to each of the three populations SC₁, SC₂, SC₃, as illustrated schematically in FIG. 3.

For each test scenario, the population of identical samples is placed in an oven (test bench) at the determined test temperature, and the samples are supplied with current I, at a determined current density J, for several hours. The resistance of each of the samples increases over time. For each scenario, the resistance of each sample i is recorded as a function of time: these are the curves in FIG. 4. The failure time TFᵢ of each sample i is determined as the time at which the resistance increases quite abruptly before then rising linearly. In other words, the failure is accompanied by a resistance jump observed on the curves in FIG. 4. It is assumed that the distribution of the cumulative failure times TFᵢ can be plotted as a function of the failure rate on a lognormal scale for each test scenario.

For each test scenario SC₁, SC₂, SC₃, a corresponding straight distribution line D₁, D₂, D₃ of the cumulative failure times in a confidence interval, for example in a 95% confidence interval, may thus be plotted on the basis of the measured failure times (FIG. 5).

Black's equation can then be applied to these failure time distributions by using a multilinear treatment, and more precisely a multilinear regression, in order to determine the three Black parameters A_{b}, n_{b} and Eₐ as well as the standard deviation (or dispersion) σ: the values found for these Black parameters are the values representative of the tested interconnect structure and therefore the technology in question, that is to say the parameters which model this interconnect's mechanism of failure by electromigration. The use of multilinear regression is known, and it is advantageous in so far as it makes it possible to determine confidence or uncertainty intervals for the extracted parameters A_{b}, n_{b}, Eₐ and σ.

Once the three applicable Black parameters have been determined, with a confidence interval, Black's equation then makes it possible to calculate the median lifetime MTTF (in hours) for each of these test scenarios, with a confidence interval: this is a direct application of Black's equation, with the values determined for the parameters A_{b}, n_{b} and Eₐ and the values J and T for the test scenario in question. FIG. 6 thus illustrates, as a function of the corresponding value of 1/kT, the three calculated median lifetime values MTTF for each of the three test scenarios in FIG. 3: MTTF(1) for scenario SC₁, MTTF(2) for scenario SC₂ and MTTF(3) for scenario SC₃. In one example, in order to define the three test scenarios, three pairs of parameters T, J are selected on the basis of a choice of three temperature values, for example 260° C., 300° C., 350° C., and two values for the applied current I, for example 0.2 mA and 0.1 mA (the current density J is equal to the applied current I divided by the conduction area of the interconnect structure under test).

By using Black's equation EQB and the standard deviation σ, it is then possible to plot the curve in FIG. 7 of the distribution of the cumulative failure times, which is substantially a straight line of slope a; and to determine the lifetime of the tested interconnect structure under the operational working conditions intended for the product in question, that is to say with a maximum current density Jₒₚ and the temperature Tₒₚ which are operationally intended for this product, for a determined failure rate u, typically 0.1%, by extrapolation to the origin: the mean lifetime, extrapolated to the working conditions, is given by the point of intersection of the straight line of slope σ and the time axis. In practice, the operational current density corresponds to the mean value of the applied current, which may be a direct, alternating or pulsed current, divided by the area of the tested interconnect structure.

In practice, however, it has been observed that with the most recent technology nodes, and notably those in which the interconnect lines are obtained using copper damascene methods, the test samples do not all behave in the same way in respect of the electromigration phenomenon. In certain test structures, it has been observed that for the same test scenario, the distribution of the cumulative failure times is an at least bimodal or trimodal distribution, that is to say in contrast to that which is represented in FIG. 5, the distribution curve of the cumulative failure times which is plotted on the basis of the measurements carried out on the samples under test is no longer a straight line in a lognormal graph, but a sinuous curve Cₑₓₚ as illustrated FIG. 8, in an example of a bimodal distribution.

Thus, with the conventional process of extracting the parameters A_{b}, Eₐ, n_{b}, and σ as described above, there are errors in the calculation of these parameters, which affect the recalculated distribution (FIG. 6) and therefore the extracted lifetime under the operational conditions and with the intended failure rate (FIG. 7).

Specifically, in the case of a multimodal distribution of the cumulative failure times, assigning a single triplet of Black parameter values and a single parameter σ for modeling the behavior of the interconnect structure under test does not give a result representative of the physical phenomenon associated with electromigration.

In the invention, it has been discovered that it is necessary and possible to discriminate between the various failure mechanisms encountered, in order to model each mechanism separately.

This therefore involves discriminating between the test samples in order to plot one distribution per group of discriminated samples, corresponding to distinct mechanisms of failure by electromigration.

Notably, in one example of a test structure, it was possible to observe a bimodal distribution and these two distributions could be correlated with two types of defects observed by microscopy. The first distribution C_{ef} (FIG. 8) corresponded to early failures, corresponding to structural defects, typically cavities or voids in the interconnect line metal, lying in proximity to a via. The second distribution C_{cf} (FIG. 8) corresponded to late failures, due to these same structural defects but located far from the vias.

Not differentiating between these samples in the method for characterizing the lifetime of the interconnects, as described above, will necessarily lead to determination of the Black parameters and the parameter σ which are incorrect, because these parameters model a single mechanism of failure by electromigration, while in reality there are a plurality of failure mechanisms corresponding to a plurality of distributions, such as for example the two distributions C_{ef} and C_{cf} observed in FIG. 8 for a bimodal case. Since the Black parameters and the parameter σ are erroneous, this will affect the entire characterization process: in the end, the lifetime extrapolated to the operational conditions will not be correct.

### SUMMARY OF THE INVENTION

It is an object of the invention to overcome this technical problem of characterizing the lifetime of interconnects, when there is a distribution of the sample failure times which is no longer monomodal but at least bimodal.

The invention thus relates to a characterization method capable of separating the samples according to their failure mode, on the basis of a physical characteristic which is easy to measure and not based on simple observation of the recorded distribution curves.

In the invention, it has been possible to show that the resistance jump has an absolute height, or amplitude, which differs according to the failure mode, and especially that this resistance jump has a much larger amplitude for early failure times than for late failure times. Such a physical characteristic is easy to utilize in an automated fashion by adding, in the resistance measurement step of the usual characterization method, a step of measuring the amplitude of the resistance jump at failure for each sample, and a step of discriminating between the samples on the basis of the value of this increase, with a view to extracting the Black parameters and the parameter σ from a group of samples responding homogeneously to the same failure mechanism.

In this way, a more refined and more accurate extrapolation of the characterization tests is achieved because it is possible to determine the lifetime, under operational conditions and for an expected failure rate, for each group of samples.

If each of the groups achieves at least the lifetime which is expected for the product or application in question, the interconnect structure is “qualified”. If one group does not achieve this lifetime, then this will be an indication that the technology needs to be improved further (materials, steps of the method, etc.).

In this case other applications/products, for which a shorter lifetime of the interconnect structures is sufficient, may be sought for this technology.

### BRIEF DESCRIPTION OF THE DRAWINGS

FIG. 1 is a view in section of an interconnect line corresponding to a damascene method;

FIG. 2 illustrates an interconnect structure and an associated test bench used in a lifetime characterization method;

FIG. 3 is a block diagram representing the test scenarios, each carried out on a population of identical interconnect samples, which are used in the methods for characterizing the lifetime of interconnect structures;

FIG. 4 shows the curves of resistance as a function of time, which are recorded for each sample under test;

FIG. 5 shows the distribution curves of the cumulative failure times in a lognormal representation, which are obtained for each test scenario;

FIG. 6 illustrates the calculation of the median lifetimes for each test condition, on the basis of the Black parameters determined by multilinear regression from the curves in FIG. 5;

FIG. 7 is the distribution curve of the cumulative failure times under the operational conditions as a function of the failure rate;

FIG. 8 is an illustration of an example of a bimodal distribution of the samples of a population under test;

FIG. 9 illustrates the bimodal distribution, demonstrated by resistance jump discrimination as employed in the invention, of the samples of a population under test; and

FIG. 10 is a flow chart of a characterization method according to the invention employing a step of discrimination as a function of the amplitude of the resistance jump at failure.

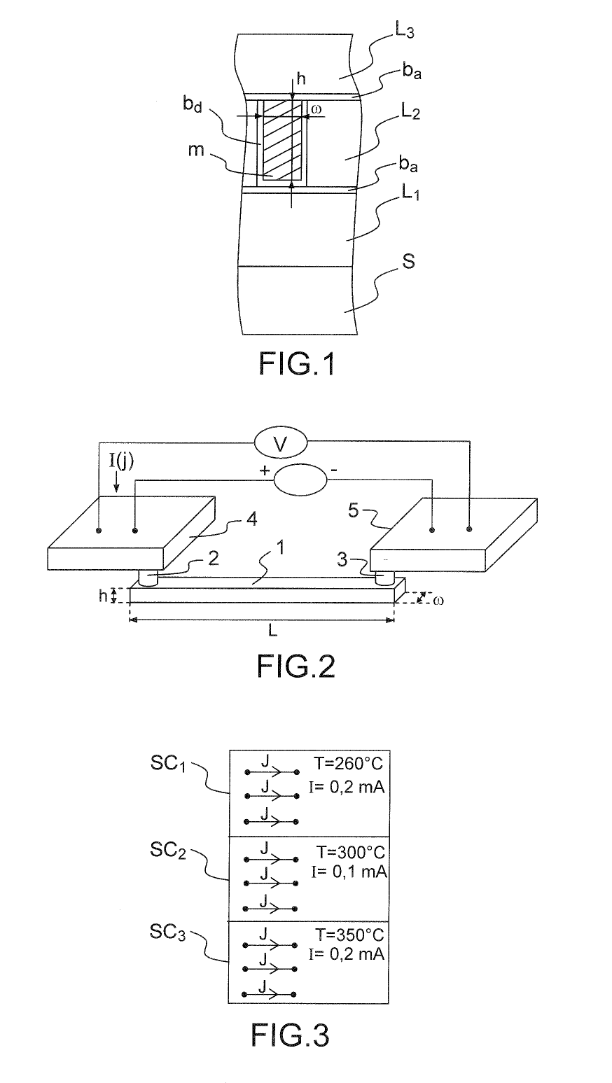

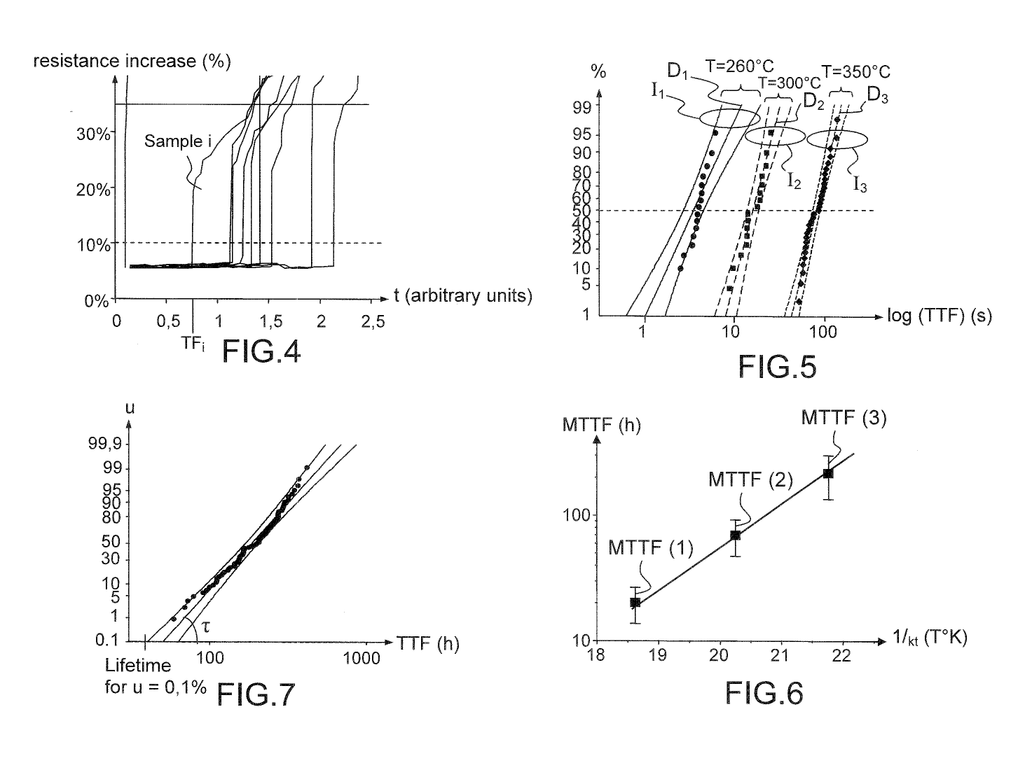

### DETAILED DESCRIPTION

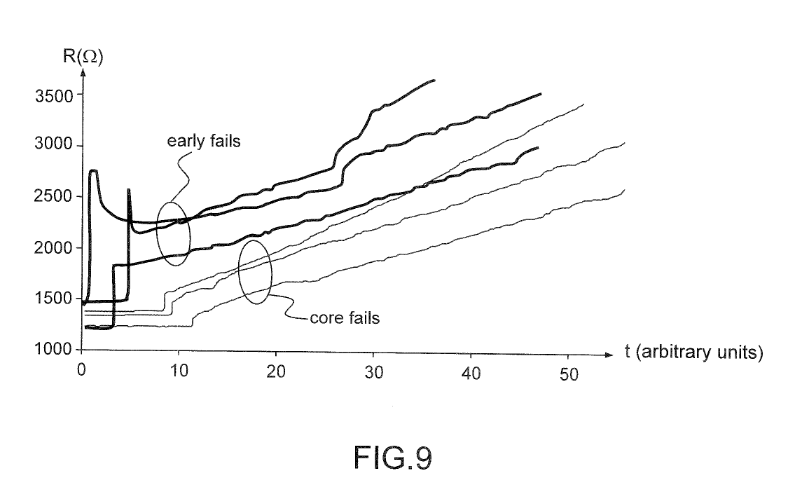

FIG. 9 illustrates the resistance curves recorded for each of the samples of a population of samples i subjected to the same test scenario (J, T).

It is known that the failure time of an interconnect structure sample corresponds to a sharp increase in its resistance.

FIG. 9 illustrates the link which is made in the invention between the amplitude of this sharp resistance variation and the type of failure time: early or late, and therefore the type of mechanism of failure by electromigration. If the amplitude variation is high, typically of the order of at least 500 ohms, they are samples with an early failure time: in the example, for one sample the resistance changes sharply from 1250Ω to 1800Ω, i.e. a jump with an amplitude of 550 ohms; for another, from 1400Ω to 2700Ω, i.e. a jump with an amplitude of 1300 ohms, and for another from about 1490Ω to 2500Ω, i.e. a jump with an amplitude of 1010 ohms. If the amplitude is smaller, they are samples with a late failure time. There are three samples in this case in the example illustrated in FIG. 9: for one sample the resistance changes sharply from 1250Ω to 1350Ω, for another, from 1400Ω to 1500Ω and for another in turn from 1450Ω to 1550Ω, i.e. a jump with an amplitude of 100 ohms each time in this example.

Thus, in the invention, in addition to the detection of the failure time which is obtained by detecting a resistance jump, for example a 5% increase in the resistance, a step of measuring the increase value of the resistance at the failure time is added in order to make a discrimination between the samples on the basis of this value relative to a determined threshold.

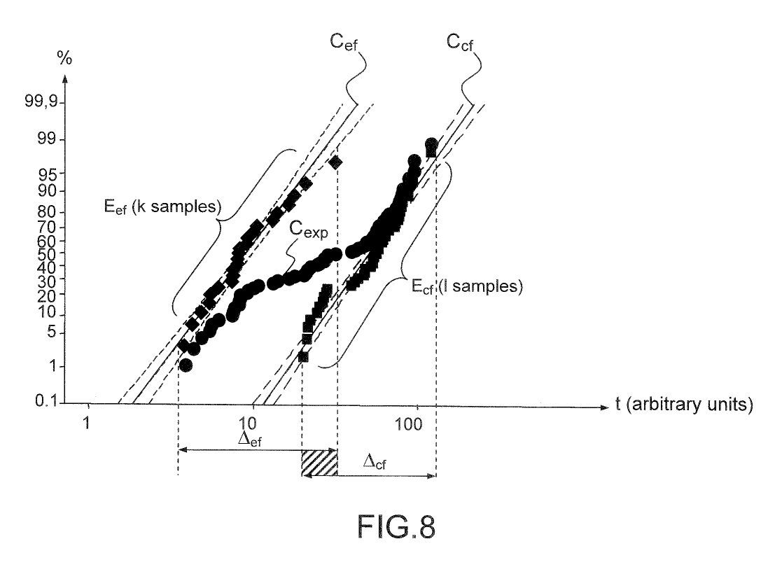

Preferably, the measured increase value is the absolute value of the increase in the resistance at the failure time, that is to say the amplitude of the resistance jump at failure. In the example of a bimodal distribution as illustrated in FIG. 8, the amplitude comparison threshold will for example be taken equal to 500 ohms.

In a variant, the measured increase value is the relative value, that is to say an increase factor, and the comparison threshold will be equal to a factor. In the example, the increase factor varies by a ratio of 5 to 10 between the group of samples with early failure (increase factor varying in the example of FIG. 8 between 44 and 90% increase) and that with late failure (increase factor of the order of 7% in the example). This ratio is however representative of a particular technology, and it varies according to the materials, the fabrication method steps, the geometry of the interconnect lines, etc. For example, determining a ratio of 5 to 10 as a sample discrimination criterion is particularly suitable for the 45, 55 or 65 nanometer CMOS technology.

Thus, adopting the absolute value of the increase as a discrimination criterion, that is to say the amplitude of the resistance jump, will generally be more advantageous because it is less linked with the technology in question.

If a test scenario is carried out on a population of N samples, this discrimination step will lead to the N samples being distributed in two groups: a group E_{ef} of k samples corresponding to an early failure time, for which the distribution curve of the failure rates may then be plotted as a function of the failure time on a lognormal scale: a straight line C_{ef} as illustrated in FIG. 8 is then obtained; and a group E_{cf} of l samples corresponding to a late failure time, for which the distribution curve of the failure rates may then be plotted as a function of the failure time on a lognormal scale: once again, a straight line C_{cf} is obtained as illustrated in FIG. 8.

For each group, the favorable conditions are then found for fine and precise determination of the Black parameters and the standard deviation parameter σ, which model the mechanism of failure by electromigration characteristic of the group.

Thus, according to the invention, a single median lifetime of an interconnect structure representative of a technology and/or a product is no longer determined; rather, each of the lifetimes corresponding to each of the groups of discriminated samples is determined. The effect of this in practice is that for each of the test scenarios of the characterization method, sorting of the samples is carried out in order to identify the samples of the late failure group. Then, for each group, as many sets of failure time measurements are obtained as there are scenarios applied (at least three).

The other steps of the method as described above with reference to FIGS. 5 to 7 are then carried out on each of the groups of samples determined in this way.

By correlating the failure mechanisms with a measurement of a physical characteristic, namely a measurement of the resistance increase value at failure, the invention thus makes it possible to improve the determination of the median lifetime of the interconnect structures in a simple way.

It is useful to note in FIG. 8 that the ranges ΔT_{ef} and ΔT_{cf} of the cumulative failure times of the two groups E_{ef} and E_{cf} partially overlap: the last point of the curve C_{ef} has a failure time which lies in the range ΔT_{cf}; and the first points of the curve C_{cf} have a failure time which falls in the range ΔT_{ef}. This clearly indicates that the value of the failure time of a sample is not a precise criterion for discriminating between the samples in relation to their failure mode.

A method for determining the lifetime of an interconnect structure under the working conditions of a given product in relation to an electromigration phenomenon, utilizing this discrimination according to the invention, will then comprise for each test sample:
a step of measuring the resistance of each test sample in order to determine a failure time of the sample by detecting a resistance jump of said sample,
a step of measuring an increase value at the failure time,
a step of comparing this resistance increase value of each of the samples, in relation to at least one predetermined threshold, in order to sort said samples into at least two groups, and
for each group of samples determined in this way, a step of calculating the lifetime of said interconnect structure on the basis of the failure times of said samples of the group in question.

In this step, it is the Black parameters A_{b}, n_{b} and Eₐ and the parameter σ that are calculated, as described above, on the basis of the failure times of the single samples of the group in question. Modeling of the median lifetime is thus obtained which is refined because it is based on test samples that are coherent in terms of failure mechanism.

For a given interconnect structure, a plurality of median lifetimes are thus obtained corresponding to different failure mechanisms. If all the extrapolated lifetimes obtained from these median lifetimes are higher than the required lifetime with the expected failure rate, the interconnect structure is characterized for the application/product in question. If this is not the case, that is to say at least one of the extrapolated lifetimes obtained is less than the expected lifetime, the technology must be improved or it is necessary to look for new applications which are less demanding in terms of expected lifetime.

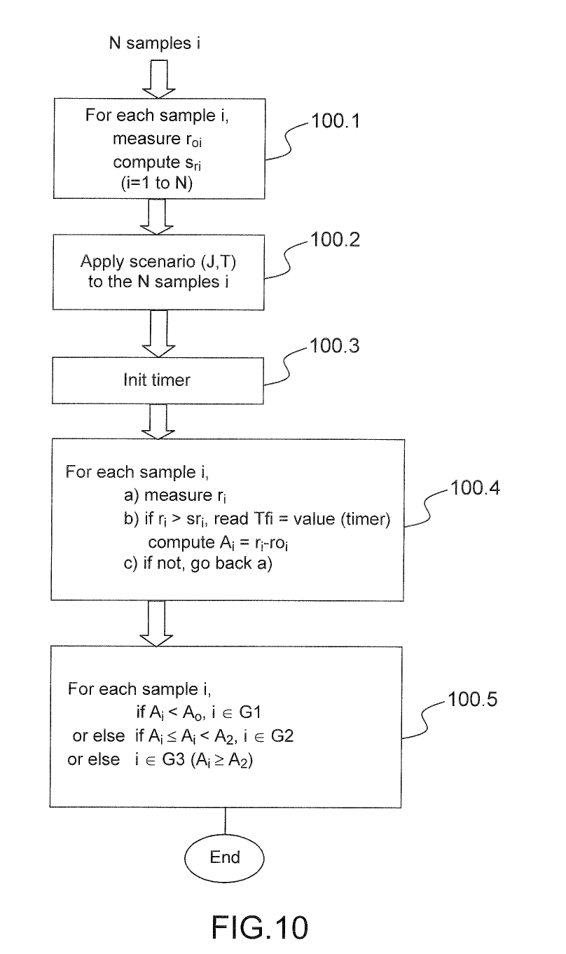

A preferred exemplary embodiment of a method for characterizing the lifetime of an interconnect structure according to the invention, with the amplitude of the resistance jump at failure as a discrimination criterion, is illustrated in FIG. 10. According to this method:

In each test scenario applied to the N test samples:
100.1 For each sample eᵢ, i=1 to N, measuring at the start of the test the value of the initial resistance r₀ᵢ, of each sample eᵢ; deducting a failure detection value sᵣᵢ, for this sample, corresponding to a resistance increase of for example 5% relative to the initial resistance, then for each sample applying the following measurement loop:
100.2: Applying the test scenario (J,T), with
100.3: initialization of a timer in order to obtain a measure of the time since the start of applying the test scenario;
   and for each sample eᵢ, i=1 to N (the samples are processed in parallel)
100.4: measuring its resistance rᵢ, at the rate of a realtime clock,
100.5: comparing the measurement rᵢ, with the threshold value sᵣ and:
   if the measurement rᵢ is greater than or equal to said threshold value, reading the value provided by the timer and storing this value as the failure time TFᵢ of the sample eᵢ; and measuring the amplitude Aᵢ of the resistance jump at the failure time TFᵢ, relative to the initial resistance r₀ᵢ(Aᵢ=rᵢ−r₀ᵢ) and storing this value Aᵢ.
   else, returning to the measurement step 100.4.

The test is terminated when the failure time of each of the samples has been detected, and the amplitude Aᵢ of the resistance jump at failure has been calculated for each of the samples.

A step 100.5 of discriminating between the samples eᵢ of the test in question is then carried out, on the basis of the value of the amplitude Aᵢ measured relative to at least one determined threshold.

In this example, at the end of each test scenario, the sample population subjected to this test is distributed into three groups G1, G2 and G3, by comparing the amplitudes of the resistance jumps of the samples in relation to two thresholds A0 and A1, which corresponds to an interconnect structure for which a trimodal distribution is observed.

Steps 100.1 to 100.5 of this method are applied for each test scenario to a population of samples under test.

At least three distribution curves of the cumulative failure times are then obtained, one per test scenario, in each group of samples G1, G2 and G3.

The rest of the characterization method is then applied to each of these groups of samples G1, G2, G3, as explained above with reference to FIGS. 5 to 7, with extraction of the Black parameters and the parameter σ, then extrapolation of the lifetime to the operational conditions, for each group.

Returning to the example of a bimodal distribution illustrated in FIG. 8, step 100.5 of the method will use a single threshold A0, for example set at 500 ohms, and two groups of samples will thereby be provided, one group E_{ef} corresponding to the k samples with early failure in FIG. 8 and one group E_{cf} corresponding to the l samples with late failure in FIG. 8, as explained above.

The invention which has just been described applies notably to bimodal distributions, as illustrated, but more generally to multimodal, notably trimodal distributions. The more refined approach obtained by discriminating between the samples according to the invention allows the interconnect structure to be characterized better in relation to operational working conditions, corresponding to an application or a finished product, making it possible to check whether the expected lifetime can be guaranteed regardless of the failure mechanism at play in said structure.

1. A method for determining the lifetime of an interconnect structure under the working conditions of a given product, comprising a step of applying at least three electromigration test scenarios to samples of said interconnect structure, each scenario being defined by a test current density and a test temperature, and each sample being subjected to one scenario out of said at least three test scenarios, and comprising for each test sample:
a step of measuring the resistance of each test sample in order to determine a failure time of the sample by detecting a resistance jump of said sample,
a step of measuring a resistance increase value of said sample at said failure time,
a step of comparing said resistance increase value of each of the samples with at least one predetermined threshold, in order to distribute said samples into at least two groups, and for each group of samples determined in this way:
a step of calculating said lifetime of said interconnect structure on the basis of the failure times of said samples of the group in question.

2. The determination method as claimed in claim 1, in which said increase value is an absolute value corresponding to the amplitude of the resistance jump at failure.

3. The determination method as claimed in claim 1, in which said increase value is a relative value corresponding to an increase factor of the resistance at failure.

4. The determination method as claimed in claim 1, in which said step of calculating said lifetime for each of said groups of samples uses modeling of a median lifetime by Black's equation, said model comprising calculation of parameters of said equation and a standard deviation parameter on the basis of said failure times of the selected samples, and extrapolation to said working conditions.

5. The determination method as claimed in claim 1, in which said representative interconnect structure comprises at least one conductive line on one level, and two vias, one via at each end of the line, for connecting the line to two current supply electrodes produced on a different level.

6. The determination method as claimed in claim 1, in which the characteristic interconnect structure is a structure obtained by a damascene method.

7. The determination method as claimed in claim 1, in which the samples are distributed in two groups, corresponding to a bimodal distribution.

8. The determination method as claimed in claim 1, in which the samples are distributed in three groups, corresponding to a trimodal distribution.
